(19) United States
(12) Patent Application Publication
(10) Pub. No.: US 2025/0228145 A1
(43) Pub. Date: Jul. 10, 2025

(54) RESISTIVE RANDOM-ACCESS MEMORY (RRAM) STRUCTURES AND METHODS OF FORMING SAME

(71) Applicant: Taiwan Semiconductor Manufacturing Company, LTD., Hsinchu (TW)

(72) Inventors: Tzu-Yu Chen, Kaohsiung (TW); Sheng-Hung Shih, Hsinchu (TW); Kuo-Chi Tu, Hsinchu (TW); Wen-Ting Chu, Kaohsiung (TW)

(21) Appl. No.: 18/409,126

(22) Filed: Jan. 10, 2024

(51) Int. Cl. H10N 70/00; H10B 63/00; H10N 70/20

(52) U.S. Cl. CPC H10N 70/8265; H10B 63/30; H10B 63/80; H10N 70/063; H10N 70/24

(57) ABSTRACT

A method of fabricating a resistive random-access memory (RRAM) structure includes forming a first patterned metallization layer; disposing a dielectric layer on the first patterned metallization layer; and etching openings exposing first contact portions of the first patterned metallization layer, each opening having an annular tapered sidewall tapering inward to a corresponding one of the first contact portions. The method further includes disposing a RRAM layer stack over the dielectric layer and conformally in the openings, etching the RRAM layer stack to form mutually isolated RRAM cells, each RRAM cell comprising a portion of the RRAM layer stack remaining after the etching and disposed entirely inside a corresponding opening; disposing an interlayer dielectric (ILD) material over the dielectric layer and over the RRAM cells; forming conductive vias passing through the ILD material and contacting the RRAM cells; and forming a second patterned metallization layer on the ILD material and electrical connecting with the conductive vias.

### BACKGROUND

The following relates to semiconductor devices, to resistive random-access memory (RRAM) cells and methods of forming the same, and the like.

Many modern electronic devices contain electronic memory configured to store data. Electronic memory may be volatile memory or non-volatile memory. Non-volatile memory is able to store data in the absence of power, whereas volatile memory is not. A resistive random access memory (RRAM) is an example of a non-volatile memory technology which advantageously has relatively simple structure and good compatibility with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an RRAM memory structure according to an example embodiment of the present disclosure, and FIG. 1B illustrates another RRAM embodiment for comparison with the presently disclosed embodiment.

FIG. 2 illustrates another RRAM memory structure (Embodiment 1) according to example embodiments of the present disclosure.

FIGS. 3A-3G illustrate various stages in the formation of a RRAM memory structure according to example embodiments of the present disclosure.

FIG. 4 illustrates a RRAM memory structure (Embodiment 2) according to example embodiments of the present disclosure.

FIGS. 5A-5D illustrate various stages in the formation of a RRAM memory structure according to FIG. 4, according to example embodiments of the present disclosure.

FIG. 6 illustrates a RRAM memory structure (Embodiment 3) according to example embodiments of the present disclosure.

FIGS. 7A-7C illustrate various stages in the formation of a RRAM memory structure according to FIG. 6, according to example embodiments of the present disclosure.

FIG. 8 illustrates a RRAM memory structure (Embodiment 4) according to example embodiments of the present disclosure.

FIG. 9 illustrates a RRAM memory structure integrated with an integrated circuit (IC) according to example embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer”, as used herein, may include a single layers or multiple layers.

The term “conductive feature”, as used herein refers to a metallization layer contact, patterned metallization layer contact, or other electrical metal contact.

The term “intermetal dielectric” (IMD) film or layer, as used herein, refers to a dielectric/insulation material(s) layer between two metal layers.

The term “interlayer dielectric” (ILD) layer, as used herein, refers to an insulating structure of material(s) placed between two conductive layers.

The term “well” as used herein, refers to a region of a dielectric region or layer that has been formed, by etching or otherwise, to include, but not limited to, a 1) opening including annular tapered or sloped sidewalls tapering or sloping inward, 2) a frustoconical shaped opening such as a truncated cone, including tapered or sloped sidewalls, 3) a trench including tapered or sloped sidewalls, or 4) an opening including tapered, angled, or sloped sidewalls.

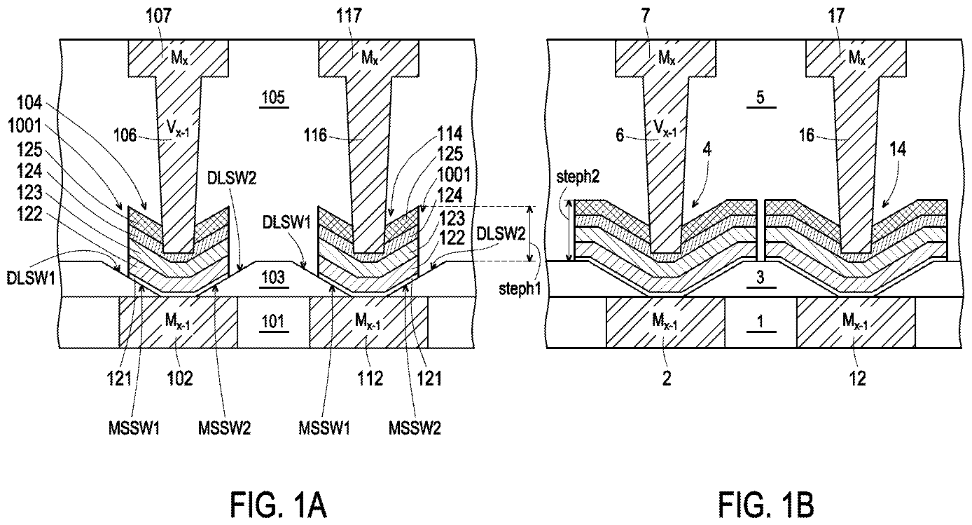

A type of non-volatile memory cell sometimes referred to as a resistive random access memory (RRAM) includes top and bottom electrodes, and a resistance switching element disposed between the top and bottom electrodes. The resistance switching element can be switched between different resistances that correspond to different data states, thereby enabling the non-volatile memory cell to store one or more bit of data. Regarding the fabrication of the memory cells, a bottom electrode layer, a resistance switching layer, and a top electrode layer may be formed over a bottom interconnect structure and a dielectric layer having an opening exposing the bottom interconnect structure. Sometimes, the memory cell may have a raising portion on a top surface of the dielectric layer, which results in a step height between a top surface of the memory cell and a periphery region (e.g., logic region), which may decrease a process window of the following metallization layer Mₓ when the memory cell is between the metallization layers Mₓ and Mₓ₋₁. (See FIG. 1B). Large step height differences between the RRAM cell height and a periphery stricture is disadvantageous to photolithography uniformity, especially as the RRAM cell sizescales down. The RRAM top via and metal window are sacrificed for RRAM cell step height, result in a RRAM top via open issue.

FIG. 1A illustrates an RRAM memory structure according to an example embodiment of the present disclosure, and FIG. 1B illustrates another RRAM embodiment for comparison with the presently disclosed embodiment. As shown in FIG. 1A, the RRAM memory structure includes a first RRAM cell/stack 104 and a second RRAM cell/stack 114, thereby providing 2 bits of information, which states are switched by another structure (not shown) connected to the patterned metallization layer 101. While two RRAM cells 104 and 114 are shown by way of illustration, it will be appreciated that the number of RRAM cells may be much higher, e.g., in the hundreds, thousands, tens of thousands or more, based on the desired quantity of memory. The RRAM cells may for example be arranged in a two-dimensional array. FIG. 1B show an RRAM embodiment for comparison with a higher step height as compared to the presently disclosed embodiments (e.g., FIG. 1A). The RRAM structure shown in FIG. 1B includes a metallization layer 1, including: metallization layer contacts 2 and 12, a dielectric layer 3, RRAM cells 4 and 14, an ILD layer 5, conductive vias 6 and 16, and metallization layer contacts 7 and 17. Illustrated further in FIG. 1B, is a second RR

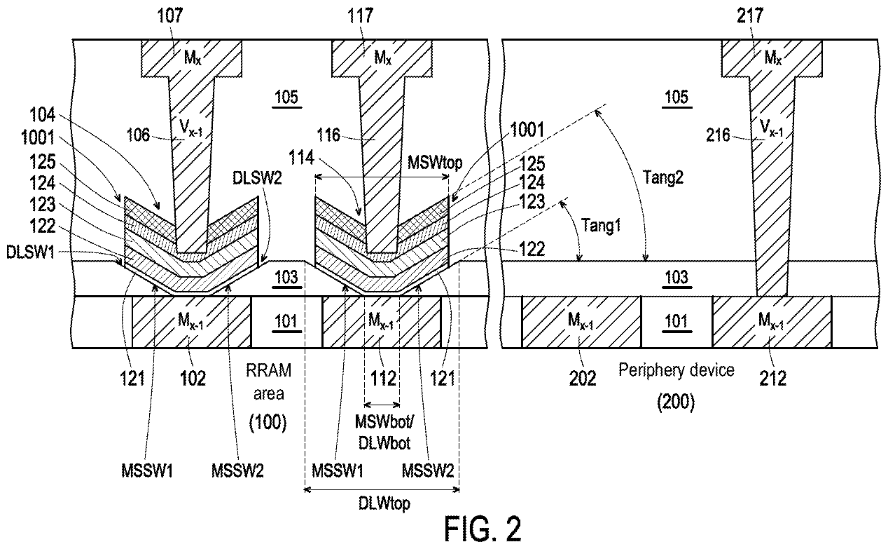

Referring to FIG. 1A and also to FIG. 2, an example semiconductor memory structure 100 of this disclosure is shown, the semiconductor memory structure 100 including a first patterned metallization layer 101 including metallization contacts 102 and 112.

Prior to describing further details of the disclosed embodiments, it is to be understood that the patterned metallization layer may be a structure connected to a semiconductor substrate (not shown) having transistors and one or more metal/dielectric layers thereon. The semiconductor substrate may be a silicon substrate. Alternatively, the substrate may include another elementary semiconductor, such as germanium; a compound semiconductor such as silicon carbide or gallium arsenide (GaAs); an alloy semiconductor such as silicon germanium; or combinations thereof. In some embodiments, the substrate is a semiconductor on insulator (SOI) substrate. The substrate may include doped regions, such as p-wells and n-wells. The transistors are formed by suitable transistor fabrication processes and may be a planar transistor, such as polysilicon gate transistors or high-k metal gate transistors, or a multi-gate transistor, such as fin field effect transistors. After the transistors are formed, one or more metal/dielectric layers of a multi-level interconnect (MLI) is formed over the transistors.

The metal/dielectric layer/metallization layer 101 includes one or more conductive features 102, 112, 202 and 212 embedded in an interlayer dielectric (ILD) layer. The ILD layer may be silicon oxide, fluorinated silica glass (FSG), carbon doped silicon oxide, tetra-ethyl-ortho-silicate (TEOS) oxide, phosphosilicate glass (PSG), borophosphosilicate glass (BPSG), Black Diamond® (Applied Materials of Santa Clara, Calif.), amorphous fluorinated carbon, low-k dielectric material, the like or combinations thereof. The conductive features 102 and 112 may be aluminum, aluminum alloy, copper, copper alloy, titanium, titanium nitride, tantalum, tantalum nitride, tungsten, cobalt, the like, and/or combinations thereof. The substrate may also include active and passive devices, for example, underlying the metal/dielectric layers 101. These further components are omitted from the figures for clarity.

Again, referring back to FIG. 1A and FIG. 2, a dielectric layer 103 is disposed on the patterned metallization layer 101, and the dielectric layer 103 has an opening/well/trench 1001 for each RRAM cell aligned with conductive features 102 and 112, where each opening 1001 is defined by a bottom, a top, a bottom width, a top width greater than the bottom width, a tapered first sidewall extending from the bottom to the top, and a tapered second sidewall extending from the bottom to the top. Stated another way, each opening 1001 has an annular tapered sidewall tapering inward to a corresponding contact portion of the metallization layer contacts.

For each RRAM structure, a resistive random-access memory (RRAM) cell 104 and 114 is disposed on the dielectric layer 103 and aligned with the dielectric layer well, each RRAM cell including a barrier layer 121, a bottom electrode layer 122, a resistance switch layer 123 and a top electrode layer 124, as well as a hard mask layer 125. The RRAM cells 104 and 114 are defined by a cell width which is less than the dielectric layer well top width, wherein the RRAM cell is located within the well and extends to a first portion of the well first sidewall DLSW1 and extends to a first portion of the well second sidewall DSLSW2, and the well first sidewall DLSW1 and the well second sidewall DLSW2 each have a respective second portion that is free of any contact with the RRAM cells 104 and 114. An interlayer dielectric (ILD) layer 105 is disposed on the RRAM cells 104 and 114, the ILD layer 105 having vias 106 and 116 passing therethrough that are connected to the top electrode layer 124 of the respective RRAM cells 104, 114. A metallization layer including an embedded second conductive features 107 and 117 is connected to the vias 106 and 116 to electrically connect the metallization layer contact 107, 117 to (the top electrode layer 124 of) the RRAM cells 104 and 114.

Also shown, with particular reference to FIG. 2, is a periphery device or electrical connection 200 that in the nonlimiting illustrative example is an electrical connection that includes an additional via 216 and metallization layer contacts 217. The periphery device or electrical connection may serve as an interface or connection with a logic processing circuit, etc. As another nonlimiting illustrative example, the periphery device or electrical connection could be an electrical device such as a back end-of-line (BEOL) capacitor (not shown).

It is to be understood that while many of the figures show a double RRAM cell structure, for brevity, most of the description that follows describes only one of the two shown, understanding that both RRAM cell structures are identical.

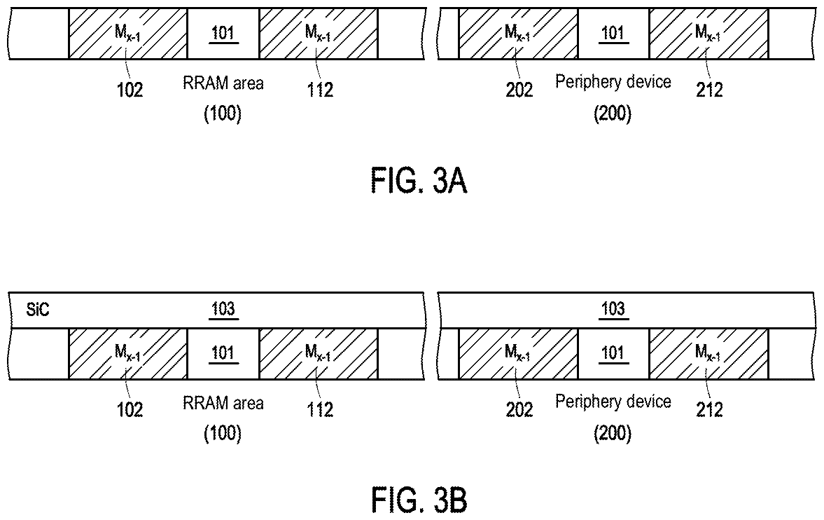

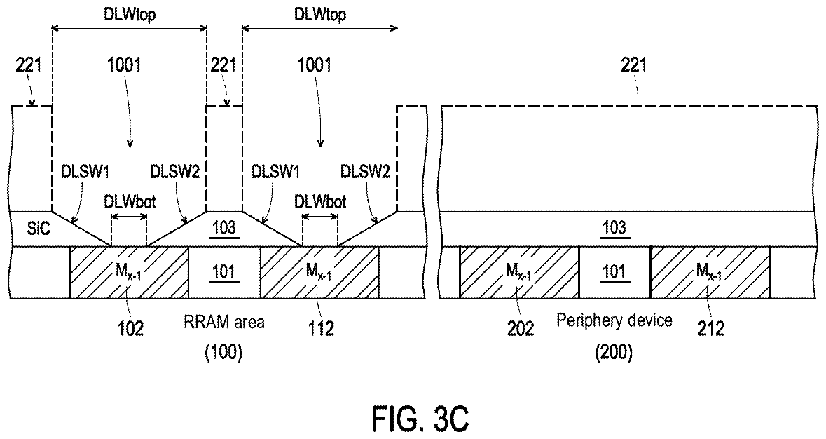

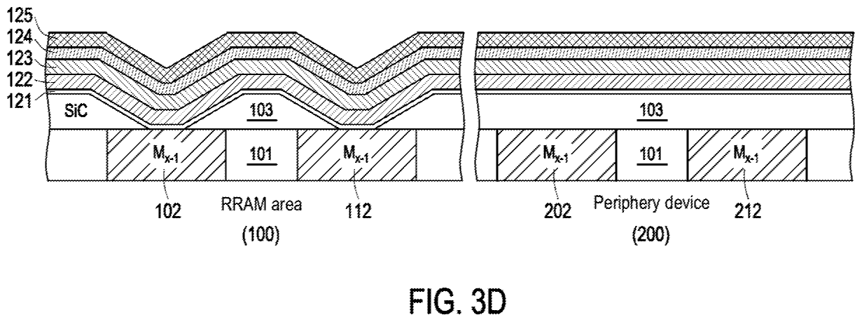

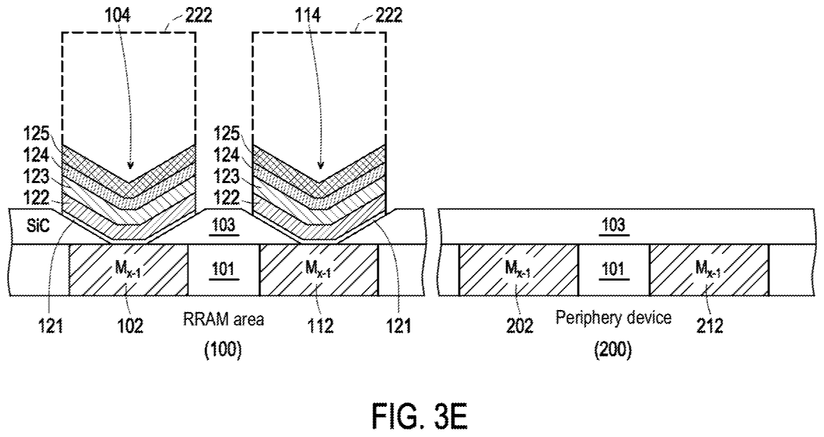

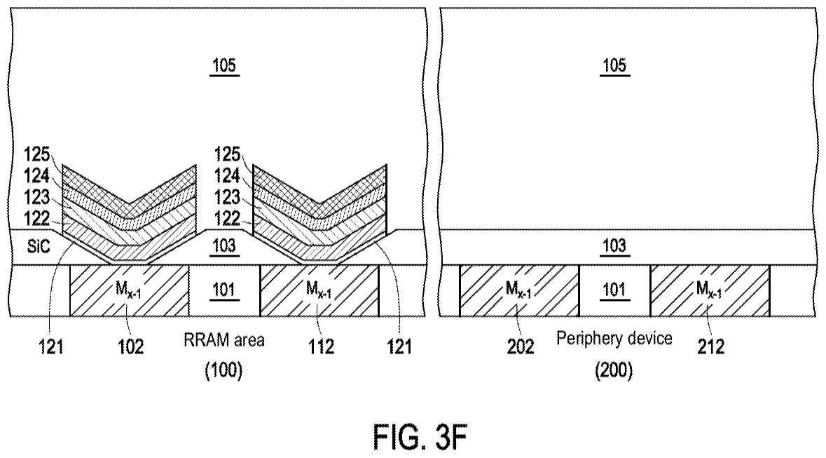

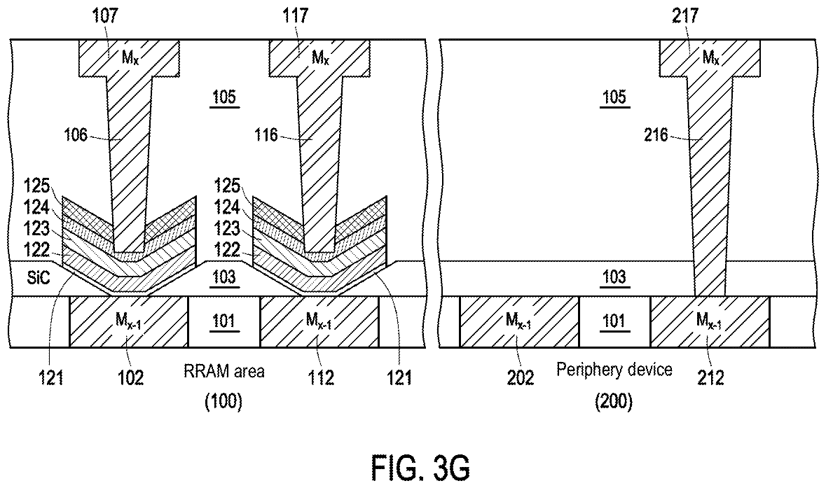

In some embodiments, a RRAM structure including a RRAM cell or layer stack 104 is fabricated by forming the opening 1001 (see FIG. 3C which shows a side sectional view of the under-fabrication device after formation of the opening 1001) of the dielectric layer 103 associated with the patterned metallization layer that is connected to another device or structure and used to switch the RRAM on and off. As seen in FIG. 3C, the opening 1001 or well includes tapered sidewalls DLSW1 and DLSW2, and the RRAM cell 104/114 fabricated in the opening 1001 as shown in FIGS. 1A and 2 is aligned with a vertical axis of the opening and formed within the opening 1001 such that the width of the RRAM cell 104/114 is less than the maximum width of the opening 1001, i.e. the top width of the opening which is defined by the tapered or sloped sidewalls of the opening in the dielectric layer 103. In other words, the RRAM cell or stack 104/114 is formed using photolithography and etching processes to reduce the diameter within and over a tapered portion of the dielectric layer 103, thereby advantageously reducing the step height between a top surface of the memory cell and a periphery region (e.g., logic region). In other words, comparing FIGS. 1A and 1B, by forming the RRAM cell or stack 104/114 entirely within the opening 1001 a RRAM cell step height steph1 of the presently disclosed embodiments (FIG. 1A) is less than the RRAM cell step height steph2 of previous embodiments (FIG. 1B) in which the RRAM cell or stack 4/14 extends outside of the opening. According to an example embodiment, steph1 is 200A to 900A. More specifically, according to another example embodiment, steph1 is 300A. By way of example, according to an example embodiment, the width of the RRAM stack 104, 114 is reduced from approximately 100 nm (for RRAM stack 4, 14 of FIG. 1B) to 75 nm (for RRAM stack 104, 114 of FIG. 1A), or another example embodiment the RRAM stack width of RRAM stack 104, 114 of FIG. 1A is in a range of 65 nm-85 nm. The resulting step height reduction obtained by the RRAM cell being entirely inside the opening 1001 provides a relatively improved top via/metal uniformity for a reduced step height. In addition, disclosed herein is the use of extra low-k (ELK) dielectric material 105 for the gap fill for achieving a reduced step height and reduced aspect ratio associated with a RRAM structure according to example embodiments. According to another example embodiment, a thickness of the RRAM hard mask layer 125 is approximately 100-200A, a thickness of the RRAM top electrode layer 124 is approximately 200-250A, a thickness of the RRAM film resistive switch layer 123 is approximately 20-30A, and a combined thickness of the RRAM bottom electrode 122 and barrier layer 121 is approximately 80-150A. These low thicknesses advantageously further reduce the step height.

According to another aspect of this disclosure, an integrated circuit including a RRAM memory cell, as disclosed, is provided in accordance with various exemplary embodiments. The intermediate stages of fabricating the RRAM cell are illustrated. Variations of the embodiments are discussed. Throughout the various views and illustrative embodiments, like reference numbers are used to designate like elements.

With particular reference now to FIG. 2 the RRAM memory structure (Embodiment 1) is further described according to example embodiments of the present disclosure. The memory structure 104/114 has a tapered profile. For example, sizes of the bottom electrode 122, the resistance switch element 123, the top electrode 124, and the hard mask layer 125 have tapered sidewalls. According to example embodiments, the memory structure 104/114 has sidewalls slanted with respect to a direction normal to a top surface of the dielectric layer 103. The slanted sidewall MSSW1 and MSSW2 of the memory structure 104/114 may land on the tapered sidewalls DLSW1 and DLSW2 of the dielectric layer 103. The tapered sidewalls DLSW1 and DLSW2 of the dielectric layer 103 are part of the opening 1001 etched in the dielectric layer 103 (see FIG. 3C) and may have a first portion covered by the memory structure 104/114 (e.g., the hard mask 125, the top electrode 124, the resistance switch element 123, the bottom electrode 122, and the barrier layer 121) and a second portion free of coverage of the memory structure 104/114. The result is a memory structure 104/114 that is not formed on the flat top surface of the dielectric layer 103, thereby reducing a step height between a top surface of the memory structure 104/114 and the top surface of the dielectric layer 103.

The dielectric layer opening 1001 which includes tapered sidewalls DLSW1 and DLSW2 is further defined by an opening top width DLWtop and bottom width DLWbot, where DLWtop is greater than DLWbot.

The RRAM cells 104/114 slanted sidewalls MSSW1 and MSSW2 include a sidewall of the barrier layer 121, bottom electrode 122, a sidewall of the resistance switch element 123, a sidewall of the top electrode 124, and a sidewall of the hard mask 125. The sidewalls of the bottom electrode 122, resistance switch element 123, top electrode 124, and hard mask 125 are substantially aligned with each other. In some embodiments, the slant or taper is defined as an angle Tang1 between a slant sidewall of RRAM cell 104/114 or dielectric layer side wall, relative to the top surface of the dielectric layer 103, which may include a range of angles. An angle Tang2 defines the slant or taper of the RRAM cells 104/114 top layer, i.e. hard mask layer 125, relative to the top surface of the dielectric layer 103.

According to an example embodiment, as described herein, 1) Tang1 and Tang 2 are substantially equal, and Tang1 and Tang2 are substantially equal to the tapered sidewall angle of the dielectric tapered sidewalls DLSW1 and DWSW2, relative to a top surface of the dielectric layer 103; and/or 2) the RRAM cell top width MSWtop and the RRAM cell bottom width MSWbot are substantially equal, and less than the dielectric opening 1001 top width DLWtop; In other words, the RRAM cell is entirely within the borders of the opening 1001. According to an example embodiment, Tang1 and Tang2 equal 5-75 degrees. More specifically, according to another example embodiment, Tang1 and Tang2 equal 38-45 degrees. According to an example embodiment, MSWbot is equal to 10 nm-70 nm, and MSWtop is equal to 50 nm-150 nm. More specifically, according to another example embodiment, MSWbot is equal to 40 nm and MSWtop is equal to 70 nm-90 nm.

The interlayer dielectric layer 105 is deposited over the memory structure 104/114 using a suitable deposition technique. The interlayer dielectric layer 105 material may be silicon oxide, an extreme or extra low-k (ELK) dielectric such as a porous silicon oxide layer, or other commonly used interlayer dielectric material. After the formation of the interlayer dielectric layer 105, an opening is etched in the interlayer dielectric layer 105 to expose a top electrode 124. Subsequently, the opening is filled with a conductive feature material, such as a metal. The conductive filling material may also include one or more liner and barrier layers in addition to a metal conductor. The liner and/or barrier may be conductive and deposited using chemical vapor deposition (CVD) or physical vapor deposition (PVD). The metal may be deposited using PVD or a plating method such as electrochemical plating. After the filling, a planarization process, such as chemical mechanical polishing (CMP), is performed to remove excess conductive feature material, thereby forming a conductive feature in the opening. In some embodiments, the opening may be a via opening, and the conductive feature may act as a conductive via. In some other embodiments, the opening may be a trench opening, and the conductive feature may act as a metal line.

FIGS. 3A-3G illustrate, by way of successive side sectional views, various stages in a nonlimiting illustrative embodiment of the formation of a RRAM memory structure 100 and periphery device or electrical connection 200 according to an example embodiments of the present disclosure. It is understood that additional operations may be provided before, during, and after the operations shown by FIGS. 3A-3G, and some of the operations described below can be replaced or eliminated for additional embodiments of the method. The order of the operations/processes may be interchangeable.

With reference to FIG. 3A, the process illustrated initially starts with a patterned metallization layer 101 that includes metallization layer contacts 102, 11, 202 and 212. The process step shown includes a post process to polish the RRAM area and periphery device metallization layer using CMP.

With reference to FIG. 3B, a dielectric layer 103 is formed on the metallization layer 101. The dielectric layer 103 may be silicon carbide, silicon oxynitride, silicon nitride, carbon doped silicon nitride or carbon doped silicon oxide. The dielectric layer 103 may include one or plural layers. In some embodiments, a material of a top layer of the dielectric layer 103 is selected to have a etch resistance property different from that of a bottom electrode material formed in subsequent processes. The dielectric layer 103 may have a material different from that of the interlayer dielectric (ILD) layer. The dielectric layer 103 is deposited over the metallization layer using a chemical vapor deposition (CVD) process such as plasma enhanced (PE) CVD, high-density plasma (HDP) CVD, inductively-coupled-plasma (ICP) CVD, or thermal CVD.

With reference to FIG. 3C, illustrated are process steps for forming an opening 1001 including tapered sidewalls, and a connection point at the bottom of the opening to facilitate an electrical connection of a subsequently deposited bottom electrode 122 to the metallization layer contacts 102 and 112 in metallization layer 101. Initially a photoresist layer 221 is disposed on the surface of the dielectric layer 103 by spin-on application or the like, and a photolithographic patterning is performed with a photoresist mask to form an opening in the photoresist 221 corresponding to the destined opening 1001 in the dielectric layer 103. The opening 1001 is then etched in the dielectric layer 103 to expose a portion of the conductive features 102 and 112. In some embodiments, the etching process for forming the opening 1001 may include a suitable dry etch process, such as Fluorine or Chlorine based dry etching. The etching process is performed such that the opening 1001 gets wider at its top. In other words, the dielectric layer 103 has tapered sidewalls DLSW1 and DLSW2 surrounding the opening, and the tapered sidewalls are slanted, tapered, annularly or otherwise, with respect to the top surface of the dielectric layer 103 and patterned metallization layer 101. The tapering of the opening 1001 is suitably produced by nonuniform concentration of the etchant (e.g., a fluorine- or chlorine-based gaseous or plasma etching species) with highest concentration at the center of the photoresist opening and lowest concentration at the edge of the photoresist opening. The underlying metallization layer contacts 102, 112 serve etch stops.

Stated yet another way, and with supplemental reference to FIG. 2, after the etching of the dielectric layer 103 the top surface and the bottom surface of the dielectric layer 103 extends laterally from the top and bottom of the tapered sidewalls DLSW1 and DLSW2, and the dielectric sidewall DLSW1 and DLSW2 are tapered or sloped at an angle Tang1 relative to the top surface of the dielectric layer 103 and/or metallization layer 101.

The opening 1001 may have a bottom width DLWbot adjacent to the bottom surface of the dielectric layer 103 and a top width DLWtop adjacent to the top surface of the dielectric layer 103. The bottom width DLWbot of the opening 1001 may define the contact area with the bottom electrode 122 of the RRAM (effectively, a critical dimension for a size of a bottom electrode via or BEVA). If the critical dimension is too wide, the memory cell may unnecessarily occupy too much chip area. The bottom width DLWbot can be controlled by the additional etch time after initial penetration through the dielectric layer 103—that is, more additional etch time will widen the bottom width DLWbot. The etch time can, for example, be optimized by test runs characterized by scanning electron microscope (SEM) imaging, transmission electron microscopy (TEM), surface profilometry, or the like. According to an example embodiment, DLWbot equals 10 nm-70 nm, and DLWtop is equal to 50 nm-150 nm. More specifically, according to another example embodiment, DLWbot is equal to 40 nm and DLWtop is equal to 70 nm-90 nm.

With reference to FIG. 3D, illustrated is the step of depositing a barrier layer 121, a bottom electrode 122, a resistance switch layer 123, a top electrode 124, and a hard mask layer 125 on the dielectric layer 103. These are continuous layers conformally deposited both inside the opening 1001 and on the surface of the dielectric layer 103 after stripping the photoresist 221.

The optional barrier layer 121 is a titanium nitride (TiN) layer, a tantalum nitride (TaN) layer a tantalum (Ta), or other type of layer which can act as a suitable barrier to prevent metal diffusion. Formation of the optional diffusion barrier layer 121 may be exemplarily performed using CVD, PVD, ALD, the like, and/or a combination thereof. In some embodiments, the electrode layers 122 and 124 may include titanium (Ti), tantalum (Ta), platinum (Pt), ruthenium (Ru), tungsten (W), aluminum (Al), copper (Cu), TiN, TaN, Ni, Pd, Mo, or Co, the like, and/or combinations thereof. Formation of the electrode layer(s) may be exemplarily performed using CVD, PVD, ALD, the like, and/or a combination thereof.

The bottom electrode layer 122 is deposited over the dielectric layer 103 and barrier layer 121, and extends into the tapered dielectric layer 103 opening to connect to the metallization layer contacts 102, 112, 202 and 212. A portion of the bottom electrode layer 122 in the opening of width DLWbot provides electrical contact between the bottom electrode layer 122 and the underlying metallization layer contact 102 or 112, and may be referred to as the bottom electrode via (BEVA) in some embodiments. In some embodiments, the bottom electrode layer 122 can be a single-layered structure or a multi-layered structure. For example, the bottom electrode layer can be viewed as including the barrier layer 121 and one or more electrode layers 122 over the diffusion barrier layer 121.

The resistance switch layer 123 is deposited over the bottom electrode layer 122. The resistance switch layer 123 includes a material having a variable resistance configured to undergo a reversible phase change between a high resistance state and a low resistance state. For example, the resistance switch layer 123 may include extra-high-k films. In some embodiments, the resistance switch layer 123 is a metal oxide, which may be HfOTaO, AlO, ZrO, HfZrO, AlTaO and other oxides used as a resistance switch layer 123. The metal oxide may have a non-stoichiometric oxygen to metal ratio. Depending on the method of deposition, the oxygen to metal ratio and other process conditions may be tuned to achieve specific resistance switch layer 123 properties. For example, a set of conditions may yield a low forming voltage and another set of conditions may yield a low read voltage. The metal oxide may be deposited. In some embodiments, the metal oxide is a transition metal oxide. In other embodiments, the resistance switch layer 123 is a metal oxynitride. The resistance switch layer 123 provides state switching of the RRAM by changing its resistance state. In a typical mechanism, a sufficiently high voltage (forming voltage) introduces an electrically conductive path either locally (e.g., filament formation) or homogenously. This state remains until it is reset by applying a reset voltage, hence providing a nonvolatile switchable resistance of the resistance switch layer 123.

The resistance switch layer 123 may be formed by a suitable technique, such as atomic layer deposition (ALD) with a precursor containing a metal and oxygen. Other chemical vapor deposition (CVD) techniques may be used. In another example, the resistance switch layer 123 may be formed by a physical vapor deposition (PVD), such as a sputtering process with a metallic target and with a gas supply of oxygen and optionally nitrogen to the PVD chamber. In yet another example, the resistance switch layer 123 may be formed an electron-beam deposition process.

The top electrode layer 124 is deposited over the resistance switch layer 123. The top electrode layer 124 may be metal, metal-nitride, doped polysilicon or other suitable conductive material, including titanium (Ti), tantalum (Ta), platinum (Pt), ruthenium (Ru), tungsten (W), aluminum (Al), copper (Cu), TiN, TaN, Ni, Pd, Mo, or Co, the like, and/or combinations thereof. The top electrode layer 124 may be a single or bilayer. The top electrode layer 124 may be formed by PVD, CVD, ALD, or other suitable techniques. Alternatively, the top electrode includes other suitable conductive material to electrically connect the device to other portions of an interconnect structure for electrical routing. The bottom electrode layer 122 may be similarly constructed. The top and bottom electrode layers 122 and 124 may be made of the same material, or of different materials.

The hard mask layer 125 is deposited over the top electrode layer 124. The hard mask layer 125 may be made of silicon nitride (SiN), Silicon oxynitride (SiON), or other composite dielectric layers.

In the present embodiments, the barrier layer 121, the bottom electrode layer 122, the resistance switch layer 123, the top electrode layer 124, and the hard mask layer 125 have profiles conforming to the shape of the opening 1001 in the dielectric layer 103. For example, each of the barrier layer 121, the bottom electrode layer 122, the resistance switch layer 123, the top electrode layer 124, and the hard mask layer 125 has a recess above the opening in the dielectric layer 103. In other words, these layers have a relatively concave top surface.

With reference to FIG. 3E, photolithographic etching steps are performed to define the RRAM cells 104 and 114 by removing excess barrier layer 121, bottom electrode layer 122, RRAM film/resistance switch layer 123, top electrode layer 124, and hard mask layer 125 which extends beyond the confines of photoresist regions 222. The process entails depositing a continuous photoresist layer, e.g. using a spin-on process, and performing photolithography with a suitable mask to define the photoresist regions 222. Subsequent etching removes the layer stack 121, 122, 123, 124 except where it is protected by the photoresist regions 222, namely within the previously formed openings 1001 (see FIG. 3C). In the processing resulting in the structure of FIG. 3E, the photomask used in the photolithography is designed to leave the photoresist regions 222 in areas corresponding to the RRAM cell top width MSWtop (see FIG. 2 labeling this dimension). As previously discussed, the RRAM cell top width MSWtop is smaller than the top width DLWtop of the opening 1001 (see FIG. 3C), ensuring that the RRAM cell 104 or 114 is located entirely within the respective opening 1001.

The patterning process may include a photolithography operation where a photoresist pattern 222 is deposited over the hard mask layer 125 (that is, a pattern is defined by exposing a blanket photoresist layer to light through a photoresist mask and developing the photoresist to create a photoresist pattern 222). The photoresist pattern is then used as an etch mask to protect desired portions of the hard mask layer 125). The hard mask layer 125 may then be patterned using an etching operation. In some embodiments, an etchant used to pattern the hard mask layer 125 includes an etching chemistry including gases of CF4, CLI,F, and/or other chemicals. The photoresist regions 222 are removed after the etching of the hard mask layer 125. Subsequently, the hard mask 125 is used as an etch mask to pattern the top electrode layer 124. In some embodiments, an etchant is applied to etch an exposed portion of the top electrode layer 124 that is not covered by the hard mask 125. In some suitable process sequences, the etch process stops when the resistance switch layer 123 is reached. The resistance switch layer 123 may have a higher etch resistance to etching than that of the top electrode layer 124. In this case, a different etchant is applied to continue removal the resistance switch layer 123 and underlying layers 121 and 122.

With reference to FIG. 3F, illustrated is the process step of depositing an interlayer dielectric material 105 that covers the SiC dielectric layer 103, and RRAM cells 104 and 114.

In some nonlimiting illustrative examples, the interlayer dielectric layer 105 is deposited over the memory structures 104/114 and the dielectric layer 103 layer using suitable deposition techniques. The interlayer dielectric layer 105 may be silicon oxide, extreme or extra-low-k silicon oxide such as a porous silicon oxide layer, or other commonly used interlayer dielectric material. In some embodiments in which the interlayer dielectric material 105 is an ELK dielectric, the techniques for depositing the interlayer dielectric layer 105 may be referred to as an extra-low-k (ELK) dielectric gap fill process. The interlayer dielectric layer 105 may have a material different from that of the dielectric layer 103, although this is not required. In some embodiments of the present disclosure, by fabricating the memory cell such that sidewalls of the memory cells 104, 114 are landing on the tapered or slanted sidewalls of the respective openings 1001 in the dielectric layer 103, a step height between a top surface of the memory cell and a top surface of the dielectric layer 103 is reduced, which in turn may improve photolithographic uniformity and enlarge the process window of the ELK dielectric gap fill process.

With reference to FIG. 3G, illustrated are process steps of forming conductive vias 106, 116 and 216, and metallization layer contacts 107, 117 and 217.

After the formation of the interlayer dielectric layer 105 (FIG. 3F), an opening is etched in the interlayer dielectric layer 105 to expose a top electrode 124. Subsequently, the opening is filled with a conductive feature material, such as a metal. The conductive filling material may also include one or more liner and barrier layers in addition to a metal conductor. The liner and/or barrier may be conductive and deposited using CVD or PVD. The metal may be deposited using PVD or one of the plating methods, such as electrochemical plating. After the filling, a planarization process, such as chemical mechanical polishing (CMP), is performed to remove excess conductive feature material, thereby forming a conductive feature in the opening. In some embodiments, the opening may be a combination of a via opening and a well opening, and the conductive feature may act as a combination of a metal line and a conductive via. In some embodiments, the opening may be a via (106, 116 and 216) opening, and the conductive features (107, 117 and 217) act as connections to the conductive vias. In some other embodiments, the opening may be a trench opening, and the conductive feature may act as a metal line.

In the previous examples, the RRAM cell 104, 114 is directly contacted by the interlayer dielectric layer 105 on its top and sides. In embodiments to follow, an additional spacer is added, which can improve RRAM isolation from the logic process.

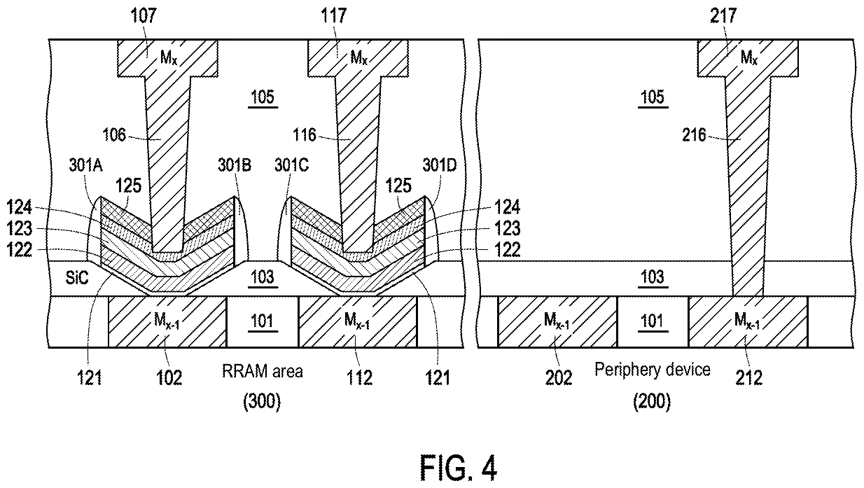

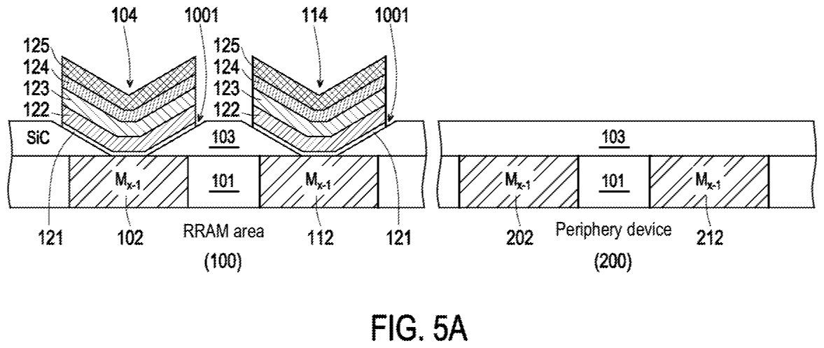

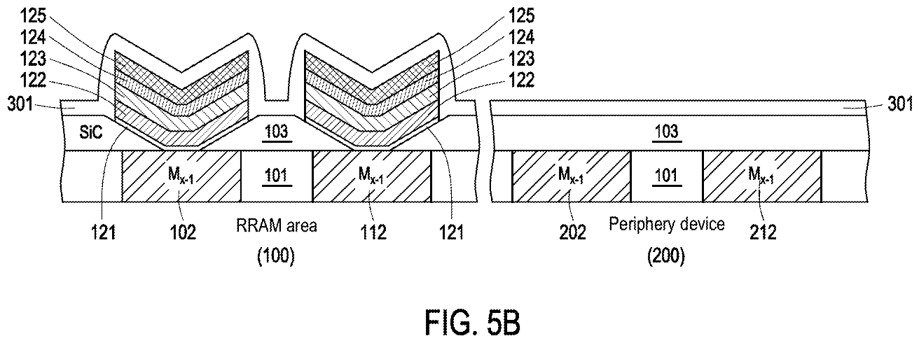

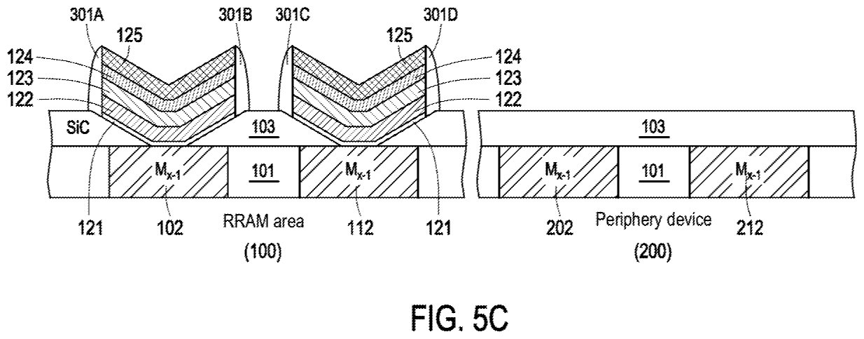

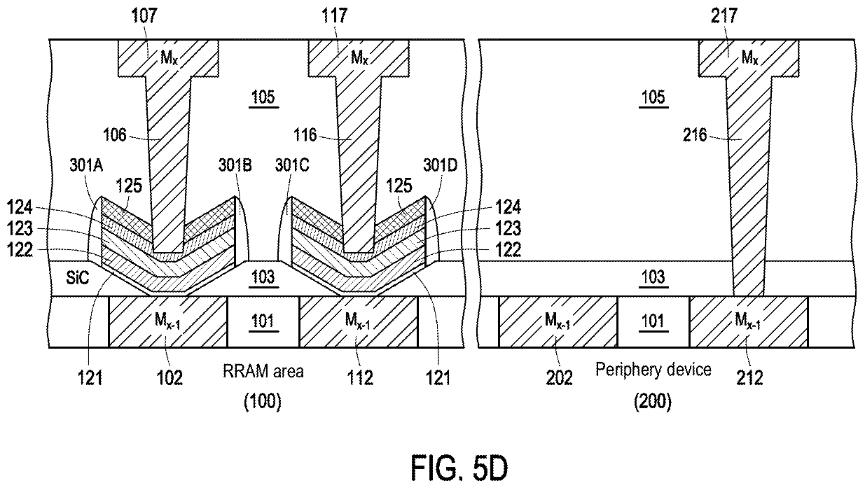

FIG. 4 illustrates a RRAM memory structure 300 (Embodiment 2) according to some embodiments of the present disclosure. The RRAM structure 300 is similar to that of FIGS. 1A and 2, but include spacers. According to this embodiment of FIG. 4, spacers 301A, 301B, 301C and 301D are formed adjacent to the RRAM cell sides to provide further isolation of the RRAM cells from periphery logic process circuits, or other structures. FIGS. 5A-5D illustrate additional or modified stages in the formation of a RRAM memory structure according to FIG. 4 to provide the spacers, according to some embodiments of the present disclosure.

With reference to FIG. 5A, shown is the resulting structure (prior to forming spacers 301A, 301B, 301C and 301D) formed by the steps shown in FIGS. 3A-3E, which provides a structure including metallization layers 101, including metallization layer contacts 102, 112, 202 and 212. In addition, the structure includes a dielectric layer 103, and RRAM cells 104 and 114 etched according to FIG. 3E to provide an opening in the hard mask layer 125 to connect to the top electrodes 124 of the RRAM cells 104 and 114.

With reference to FIG. 5B, illustrated is the step of depositing a second dielectric layer 301 over dielectric layer 103 and the RRAM cells 104 and 114. The second dielectric layer 301 is destined to be etched to leave the spacers.

With reference to FIG. 5C, illustrated is a photolithographic process of etching away the deposited spacer/dielectric layer 301 to form spacers 301A, 301B, 301C and 301D. The etch is selective to remove the material of the spacer/dielectric layer 301 without removing the material of the hard mask 125. An anisotropic etch is suitably employed that etches the portion of the spacer/dielectric layer 301 disposed on the sidewalls of the RRAM layer stack 121, 122, 123, 124, 125 more slowly than it etches the remainder of the spacer/dielectric layer 301, thereby leaving the spacers 301A, 301B, 301C and 301D.

With reference to FIG. 5D, illustrated is a process previously described with reference to FIG. 3G, including the process steps of forming conductive vias 106, 116 and 216, and metallization layer contacts 107, 117 and 217.

With reference to FIGS. 4 and 5A-5D, this process forms spacers 301A, 301B, 301C and 301D on the sidewalls of RRAM cells 104 and 114, which includes the sidewalls of the hard mask layer 125, top electrode layer 124, the resistive switch layer 123, the bottom electrode layer 122 and the barrier layer 121. The spacers 301A, 301B, 301C and 301D, and dielectric layer 301, may in some nonlimiting illustrative examples be made of silicon nitride, silicon oxynitride, and silicon oxide. In some embodiments, the spacer layer 301 may be formed by conformally depositing a spacer material layer 301 covering the top and sidewalls of the hard mask layer 125, sidewalls of the top electrode layer 124, sidewalls of the resistance switch layer 123, sidewalls of the bottom electrode layer 122 and sidewalls of the barrier layer 121. Subsequently, an anisotropic etch process may be performed to remove horizontal portions of the spacer material layer 301, and retain vertical portions (301A, 301B, 301C and 301D) of the spacer material layer 301, thereby forming the spacers. The height and width of the spacers after etching may be tuned by adjusting deposition and etching parameters.

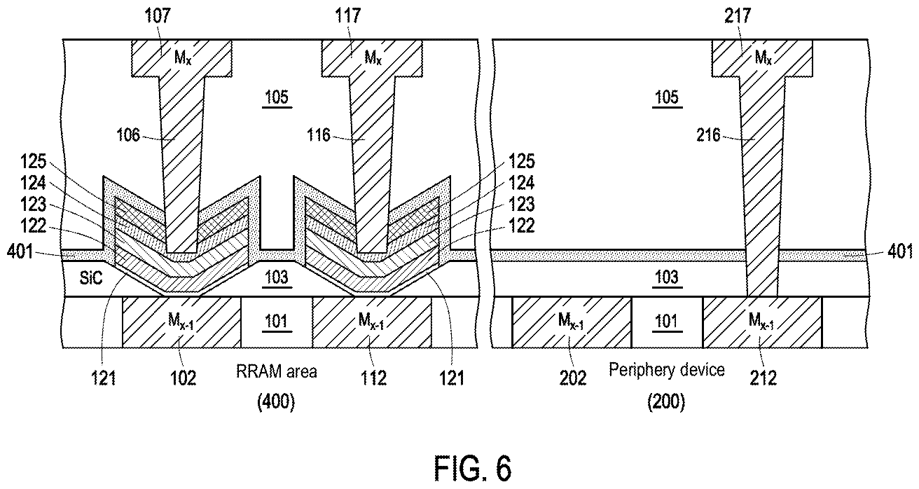

FIG. 6 illustrates a RRAM memory structure 400 (Embodiment 3) according to some embodiments of the present disclosure. According to this embodiment, an encapsulating insulating/dielectric layer 401 is deposited on the dielectric layer 103 and RRAM cells 104 and 114. This process encapsulates the RRAM cells 104 and 114 to provide further isolation of the RRAM from periphery logic process circuits, or other structures. In addition, the added encapsulating dielectric layer 401 provides supplemental isolation performance, and potentially supplemental structural support, in addition to that provided by dielectric layer 103. According to the example embodiment described, the insulating layer 401 material is SiC, which is also the material used for dielectric layer 103. The additionally deposited SiC is effectively a redeposition step that can offset any material thickness losses associated with dielectric layer 103.

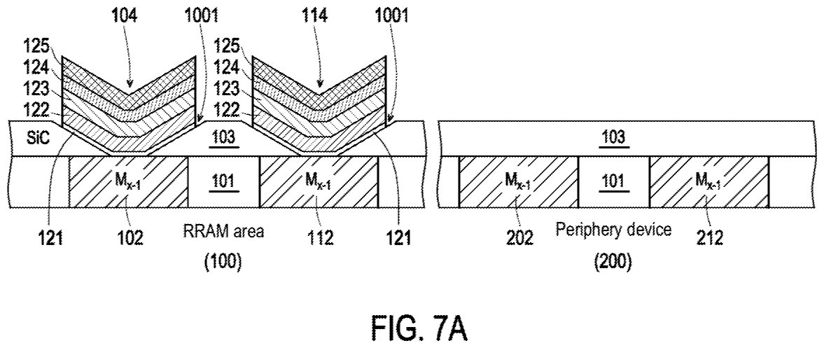

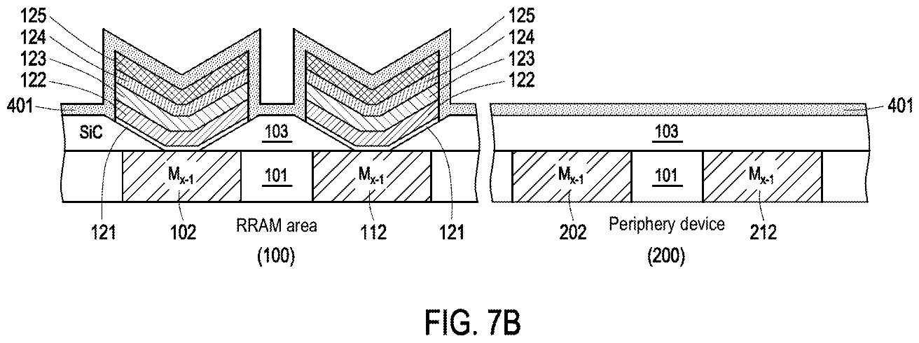

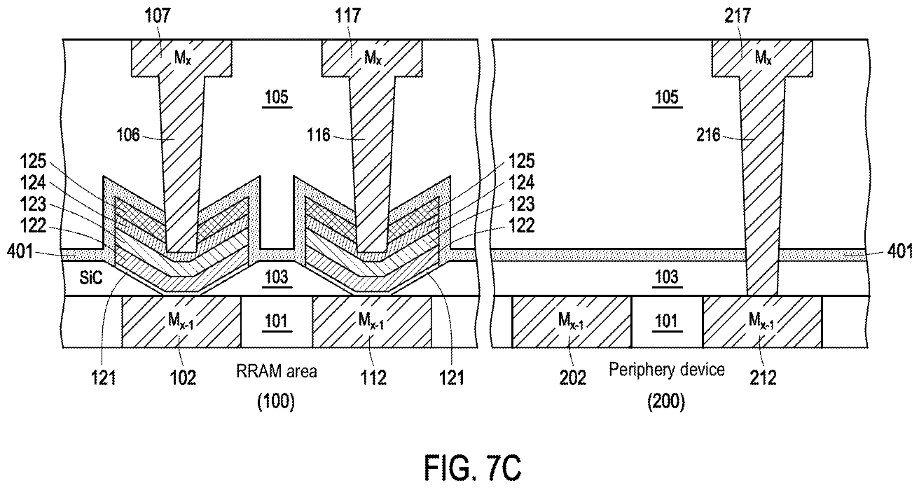

FIGS. 7A-7C illustrate various stages in the formation of a RRAM memory structure according to FIG. 6, according to some embodiments of the present disclosure.

With reference to FIG. 7A, shown is the resulting structure shown in FIGS. 3A-3E, (prior to forming encapsulating layer 401), which provides a structure including metallization layers 101, including metallization layer contacts 102, 112, 202 and 212. In addition, the structure includes a dielectric layer 103, and RRAM cells 104 and 114 etched according to FIG. 3E to provide an opening in the hard mask layer 125 to connect to the top electrodes of the RRAM cells 104 and 114.

With reference to FIG. 7B, illustrated is the step of depositing a second dielectric layer 401, over dielectric layer 103 and the RRAM cells 104 and 114, thereby providing an encapsulating insulation layer.

With reference to FIG. 7C, illustrated is a process previously described with reference to FIG. 3G, including the process steps of forming conductive vias 106, 116 and 216, and metallization layer contacts 107, 117 and 217.

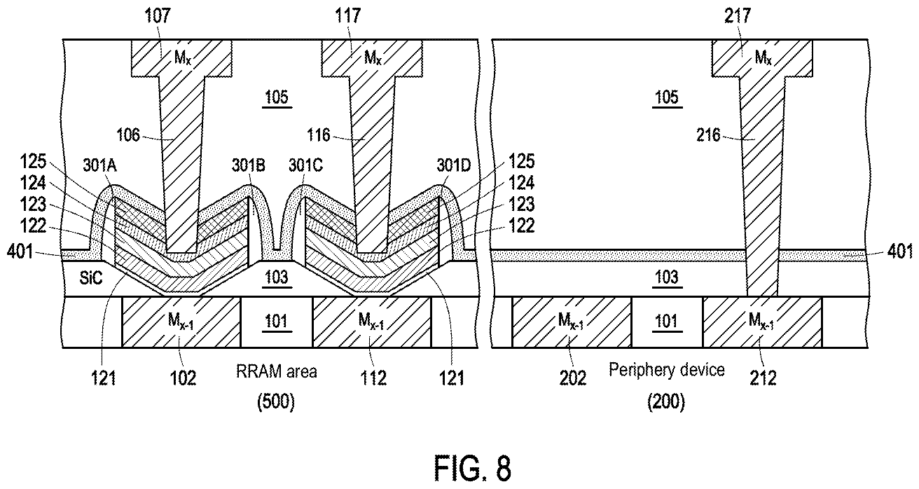

FIG. 8 illustrates a RRAM memory structure 500 (Embodiment 4) according to another example embodiment of the present disclosure. (Combination of Embodiments 2 and 3). According to this embodiment, a RRAM structure is provided that includes all the features previously described with reference to FIGS. 4-7, including a RRAM structure including spacers 301A, 301B, 301C and 301D, as well as an encapsulating insulating layer 401, which is deposited over the dielectric layer 103, spacers 301A, 301B, 301C and 301D, and the hard mask layers 125 of RRAM cells 104 and 114.

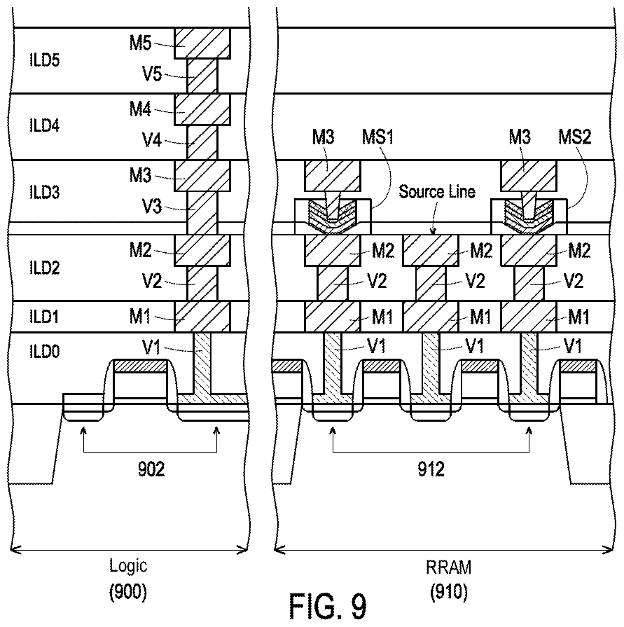

With reference to FIG. 9, illustrated is a cross-sectional view of a semiconductor device in accordance with some embodiments of the present disclosure. The semiconductor device includes a logic region 900 and a memory region 910. Logic region 900 may include circuitry, such as an exemplary logic transistor 902, for processing information received from the memory structures MS1 and MS2 in the memory region 910 and for controlling reading and writing functions of the memory structures MS1 and MS2. According to this disclosure, the memory structures MS1 and MS2 are described herein with reference to FIGS. 1A, and 2-8. In other words, the sidewalls MSS1 and MSS2 of the memory structures MS1 and MS2 are landing on tapered sidewalls of a dielectric layer as previously described.

As depicted, the semiconductor device is fabricated using four metallization layers, labeled as M1 through M5, with five layers of metallization vias or interconnects, labeled as V1 through V5. Other embodiments may contain more or fewer metallization layers and a corresponding more or fewer number of vias. Logic region 900 includes a full metallization stack, including a portion of each of metallization layers M1-M5 connected by interconnects V2-V5, with V1 connecting the stack to a source/drain contact of logic transistor 902. The memory region 910 includes a full metallization stack connecting memory structures MS1 to transistors 912 in the memory region 910, and a partial metallization stack connecting a source line to transistors 912 in the memory region 910. Memory structures MS1 are depicted as being fabricated in between the top of the M4 layer and the bottom the M5 layer. The semiconductor device also includes a plurality of ILD layers. Five ILD layers, identified as ILDO through ILD5, are depicted in FIG. 9 as spanning the logic region 900 and, ILD0 through ILD3 span the memory region 910. The ILD layers may provide electrical insulation as well as structural support for the various features of the semiconductor device during many fabrication process steps.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the memory cell is fabricated such that sidewalls of the memory cell are entirely landing on a slanted or tapered sidewall of the dielectric layer, thereby reducing the step height between a top surface of the memory cell and a top surface of the dielectric layer (e.g., a step height between the memory cell and the periphery region), which in turn may improve a subsequent low-k or extra-low-k dielectric gap fill process window.

In the following, some further embodiments are described.

In a nonlimiting illustrative embodiment, a method of fabricating a resistive random-access memory (RRAM) structure is disclosed. The method of fabricating a resistive random-access memory (RRAM) structure including: forming a first patterned metallization layer; disposing a dielectric layer on the first patterned metallization layer; etching an openings exposing first contact portions of the first patterned metallization layer, each opening having an annular tapered sidewall tapering inward to a corresponding one of the first contact portions; disposing a RRAM layer stack over the dielectric layer and conformally in the openings, the RRAM layer stack including a first conductive electrode layer, a resistance switch layer disposed on the first conductive electrode layer, and a second conductive electrode layer disposed on the resistance switch layer; etching the RRAM layer stack to form mutually isolated RRAM cells, each RRAM cell comprising a portion of the RRAM layer stack remaining after the etching and disposed entirely inside a corresponding opening; disposing an interlayer dielectric (ILD) material over the dielectric layer and over the RRAM cells; forming conductive vias passing through the ILD material and contacting the RRAM cells; and forming a second patterned metallization layer on the ILD material and electrical connecting with the conductive vias.

In another nonlimiting illustrative embodiment, a method of fabricating a semiconductor memory structure is disclosed. The method of fabricating a semiconductor memory structure including: depositing a dielectric layer over a metallization layer, wherein the metallization layer has a conductive feature therein; etching a well in the dielectric layer to expose the conductive feature, such that the dielectric layer well is defined by a bottom, a top, a bottom width, a top width greater than the bottom width, a tapered first sidewall extending from the bottom to the top, and a tapered second sidewall extending from the bottom to the top; depositing a bottom electrode layer into the well; depositing a resistance switch layer over the bottom electrode layer; depositing a top electrode layer over the resistance switch layer; patterning the bottom electrode layer, the resistance switch layer and the top electrode layer into a resistance switch cell defined by a cell width which is less than the dielectric layer well top width, such that the resistance switch cell is located within the well and extends to a first portion of the well first sidewall and extends to a first portion of the well second sidewall wall, and the well first sidewall wall and the well second sidewall each have a respective second portion that is free of any contact with the resistance switch cell; depositing an interlayer dielectric (ILD) layer over the resistance switch cell; forming a via in the ILD, the via connected to the resistance switch cell; forming a second conductive feature in the ILD, the second conductive feature connected to the via; and forming a metallization layer over the ILD, the metallization layer connected to the ILD second conductive feature.

In another nonlimiting illustrative embodiment, a semiconductor memory structure is disclosed. The semiconductor memory structure including: a first patterned metallization layer; a dielectric layer disposed on the patterned metallization layer, the dielectric layer disposed on the patterned metallization layer, the dielectric layer having a well aligned with the first conductive feature, and the well defined by a bottom, a top, a bottom width, a top width greater than the bottom width, a tapered first sidewall extending from the bottom to the top, and a tapered second sidewall extending from the bottom to the top; a resistive random-access memory (RRAM) cell disposed on the dielectric layer and aligned with the dielectric layer well, the RRAM cell including a bottom electrode layer, a resistance switch layer and a top electrode layer, and the RRAM cell defined by a cell width which is less than the dielectric layer well top width, wherein the RRAM cell is located within the well and extends to a first portion of the well first sidewall and extends to a first portion of the well second sidewall, and the well first sidewall and the well second sidewall each have a respective second portion that is free of any contact with the RRAM cell; an interlayer dielectric (ILD) layer disposed on the RRAM cell, the IML including a via connected to the RRAM cell; and a metallization layer including an embedded second conductive feature connected to the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a resistive random-access memory (RRAM) structure, the method comprising:
forming a first patterned metallization layer;
disposing a dielectric layer on the first patterned metallization layer;
etching an openings exposing first contact portions of the first patterned metallization layer, each opening having an annular tapered sidewall tapering inward to a corresponding one of the first contact portions;
disposing a RRAM layer stack over the dielectric layer and conformally in the openings, the RRAM layer stack including a first conductive electrode layer, a resistance switch layer disposed on the first conductive electrode layer, and a second conductive electrode layer disposed on the resistance switch layer;
etching the RRAM layer stack to form mutually isolated RRAM cells, each RRAM cell comprising a portion of the RRAM layer stack remaining after the etching and disposed entirely inside a corresponding opening;
disposing an interlayer dielectric (ILD) material over the dielectric layer and over the RRAM cells;
forming conductive vias passing through the ILD material and contacting the RRAM cells; and
forming a second patterned metallization layer on the ILD material and electrical connecting with the conductive vias.

2. The method of claim 1, further comprising:
prior to forming the first patterned metallization layer, forming a transistor layer comprising a plurality of transistors;
wherein the first metallization layer electrically connects the first contact portions of the first patterned metallization layer with the transistors of the transistor layer.

3. The method of claim 1, wherein the RRAM stack has a width of 85 nm or less.

4. The method of claim 1, wherein the RRAM stack has a width of 75 nm or less.

5. The method of claim 1, wherein the RRAM stack has a width of 65 nm or less.

6. The method of claim 1, wherein the RRAM stack is located within the openings to reduce an overall step height associated with the RRAM cell, as compared to the RRAM cell being located on a top surface of the dielectric layer.

7. The method of claim 1, wherein the RRAM stack bottom electrode layer material is one of TiN, TaN, Ta, Ru, W or Mo; the resistance switch layer material is one HfOTaO, AlO, ZrO, HfZrO, or AlTaO; and the top electrode layer material is one of TiN, TaN, Ta, Ru, W or Mo.

8. The method of claim 1, wherein the RRAM stack bottom electrode layer material thickness is 80-150A; the resistance switch layer material thickness is 20-30A; and the top electrode layer material thickness is 100-250A.

9. The method of claim 1, wherein the ILD material is an extra-low-k (ELK) dielectric material, and the ELK material is one or more of silicon oxide and carbon-doped silicon oxide.

10. A method of fabricating a semiconductor memory structure comprising:
depositing a dielectric layer over a metallization layer, wherein the dielectric layer has a conductive feature therein;
etching a well in the dielectric layer to expose the conductive feature, such that the dielectric layer well is defined by a bottom, a top, a bottom width, a top width greater than the bottom width, a tapered first sidewall extending from the bottom to the top, and a tapered second sidewall extending from the bottom to the top;
depositing a bottom electrode layer into the well;
depositing a resistance switch layer over the bottom electrode layer;
depositing a top electrode layer over the resistance switch layer;
patterning the bottom electrode layer, the resistance switch layer and the top electrode layer into a resistance switch cell defined by a cell width which is less than the dielectric layer well top width, such that the resistance switch cell is located within the well and extends to a first portion of the well first sidewall and extends to a first portion of the well second sidewall wall, and the well first sidewall wall and the well second sidewall each have a respective second portion that is free of any contact with the resistance switch cell;
depositing an interlayer dielectric (ILD) layer over the resistance switch cell;
forming a via in the ILD, the via connected to the resistance switch cell;
forming a second conductive feature in the ILD, the second conductive feature connected to the via; and
forming a metallization layer over the ILD, the metallization layer connected to the ILD second conductive feature.

11. The method of claim 10, wherein the resistance switch cell has a width of 85 nm or less, and the resistance switch cell width is less than the well top width.

12. The method of claim 10, wherein the resistance switch cell has a width of 75 nm or less, and the resistance switch cell width is less than the well top width.

13. The method of claim 10, wherein the resistance switch cell has a width of 65 nm or less, and the resistance switch cell width is less than the well top width.

14. The method of claim 10, wherein the bottom electrode layer material thickness is 80-150A; the resistance switch layer material thickness is 20-30A; and the top electrode layer material thickness is 100-250A.

15. The method of claim 10, wherein the ILD material is an extra-low-k (ELK) dielectric material, and the ELK material is one or more of silicon oxide and carbon-doped silicon oxide.

16. A semiconductor memory structure comprising:
a first patterned metallization layer;
a dielectric layer disposed on the patterned metallization layer, the dielectric layer disposed on the patterned metallization layer, the dielectric layer having a well aligned with the first conductive feature, and the well defined by a bottom, a top, a bottom width, a top width greater than the bottom width, a tapered first sidewall extending from the bottom to the top, and a tapered second sidewall extending from the bottom to the top;
a resistive random-access memory (RRAM) cell disposed on the dielectric layer and aligned with the dielectric layer well, the RRAM cell including a bottom electrode layer, a resistance switch layer and a top electrode layer, and the RRAM cell defined by a cell width which is less than the dielectric layer well top width, wherein the RRAM cell is located within the well and extends to a first portion of the well first sidewall and extends to a first portion of the well second sidewall, and the well first sidewall and the well second sidewall each have a respective second portion that is free of any contact with the RRAM cell;
an interlayer dielectric (ILD) layer disposed on the RRAM cell, the IML including a via connected to the RRAM cell; and
a metallization layer including an embedded second conductive feature connected to the via.

17. The semiconductor memory structure according to claim 16, wherein the RRAM cell bottom electrode layer material thickness is 80-150A; the resistance switch layer material thickness is 20-30A; and the top electrode layer material thickness is 100-250A.

18. The semiconductor memory structure according to claim 16, the RRAM cell further comprising:
a barrier layer disposed between the bottom electrode and the dielectric layer, the barrier layer material one of TiN, TaNor Ta, and the barrier layer thickness 80-150A; and
a hard mask layer disposed on the top electrode, the hard mask layer material one of SiON or SiN, and the hard mask layer material thickness is 100-200A.

19. The semiconductor memory structure according to claim 16, further comprising a hard mask layer disposed on the top electrode layer, wherein the via extends into the top electrode layer and the hard mask layer.

20. The semiconductor memory structure according to claim 16, wherein the ILD layer is an extra-low-k (ELK) dielectric material, and the ELK material is one or more of silicon oxide and carbon-doped silicon oxide.
